(19) United States
(12) Patent Application Publication
(10) Pub. No.: US 2005/0006679 A1
(43) Pub. Date: Jan. 13, 2005

(54) System and method for increasing magneting flux efficiency and cell density in MRAM design

(76) Inventors: Wen Chin Lin, Hsin-Chu (TW); Denny D. Tang, Saratoga, CA (US)

Correspondence Address: DUANE MORRIS, LLP;IP DEPARTMENT, ONE LIBERTY PLACE, PHILADELPHIA, PA, 19103-7396, US

(21) Appl. No.: 10/603,351

(22) Filed: Jun. 25, 2003

(51) Int. Cl. H01L 29/76

(52) U.S. Cl. 257/295

(57) ABSTRACT

A magnetic memory device and the method for making same are disclosed. The device uses two metal lines to control a combined magnetic field created thereof. The device has a magnetic memory element connecting to a substrate at a first end thereof, a first metal line connecting to a second end of the magnetic memory element. Further, the device has a second metal line crossing perpendicularly over the first metal line for jointly generating the combined magnetic field, wherein the second metal line is on the side of the second end of the magnetic memory element.

### BACKGROUND

The invention is generally related to magnetic random access memory (MRAM) and its fabricating method, and more particularly, to an MRAM based on a magnetic memory element such as a magnetic tunnel junction (MTJ) device.

A magnetic memory element has a structure, which includes ferromagnetic layers separated by a non-magnetic layer. Information is stored as directions of magnetization vectors in magnetic layers. If a current is caused to flow through the magnetic memory element, the magnetic memory element will act as a resistor. The resistance is a function of magnetic vector orientation. When the magnetization vectors of two layers are not parallel, the resistance should be greater. When the magnetization vectors of two layers are parallel, the resistance should be smaller. Thus, the cell exhibits two logic states: high and low tunnel junction resistance.

In fabrication, two conductor lines are typically deposited on opposite sides of (above and below) a magnetic memory element. After the first conductor is formed, the wafer will be subjected to chemical mechanical polish (CMP). The CMP process may cause non-uniform material removal over the whole wafer. The variation in thickness of the first conductor will affect the magnetic flux efficiency across the wafer. Thus, more current is required to have sufficient magnetic flux to perform writing operations for all cells consistently.

The typical MRAM is fabricated with either a diode or a transistor between the drain and the conductor line used for reading. As discussed above, the two conductor lines are typically deposited on opposite sides of (above and below) a magnetic memory element. This structure requires the fabrication of a by-pass conductor to connect the read conductor line to the diode or transistor. Since typically, the read conductor line is above the magnetic memory element, and the diode or transistor is fabricated into the substrate, the by-pass conductor must bridge a significant vertical gap. The by-pass conductor consumes additional area in each unit cell. This reduces potential memory cell density.

A method and structure is needed that would allow more precise control of conductor line thickness. This would allow thinner lines, increased magnetic flux, and therefore reduced energy consumption. A method and structure is further needed that would allow the elimination of the by-pass conductor line from a typical MRAM. This would allow for a smaller memory cell footprint, and therefore denser memory cell packing.

### SUMMARY

A magnetic memory device and the method for making same are disclosed. The device uses two metal lines to control a combined magnetic field created thereof. The device has a magnetic memory element connecting to a substrate at a first end thereof, a first metal line connecting to a second end of the magnetic memory element. Further, the device has a second metal line crossing perpendicularly over the first metal line for jointly generating the combined magnetic field, wherein the second metal line is on the side of the second end of the magnetic memory element.

According to one example of the present disclosure, the memory device can be fabricated by forming a transistor device on a substrate, forming a magnetic tunnel junction device (MTJ) connected to the transistor device through a straight line connection line, forming a first metal line over the MTJ and connected with the MTJ, forming an insulation layer over the first metal line; and forming a second metal line situated cross perpendicular to the first metal line and separated from the first metal line by the insulation region for jointly generating the combined magnetic field.

These and other aspects and advantages will become apparent from the following detailed description, taken in conjunction with the accompanying drawings, illustrating by way of example the principles of the disclosure.

### BRIEF DESCRIPTION OF THE DRAWINGS

FIG. 1 illustrates a cross-section diagram of the principal components of a typical MRAM.

FIG. 2 illustrates a cross-section diagram of the principal components of a new MRAM.

FIGS. 3a-3e illustrate the cross-section of the improved MRAM in various stages of fabrication.

### DESCRIPTION

The present disclosure uses a magnetic memory device (MRAM) as an example. It is understood that the same concept can be applied to other similar devices.

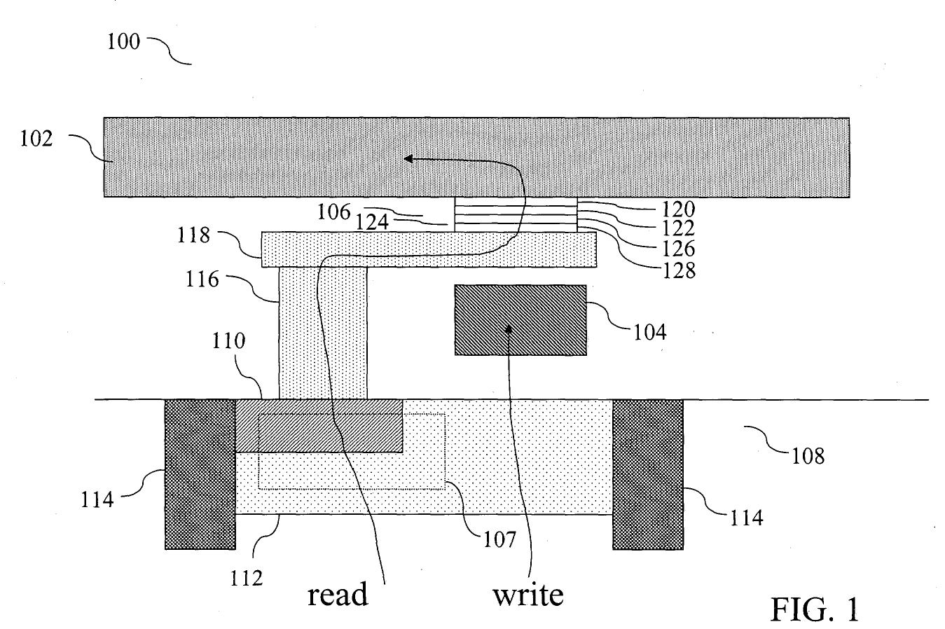

FIG. 1 illustrates a cross-section diagram of the principal components of a typical magnetic memory device (MRAM) (100). Conductor lines (102 and 104) are located above and below the magnetic memory element (106). These conductor lines cross perpendicular to each other.

As shown, a diode is (107) created in a substrate (108). The diode with its n+ region (110) and p+ region (112) is located between the substrate (108) and the magnetic memory element (106) to prevent a stray current from affecting reading operations. Dielectric barriers (114) are created in the substrate (108), around the diode to isolate the cell (100) from other cells. Several sets of inter-metal layers and connecting vias (not shown for clarity) are typically located between the diode (107) and the first conductor line (104). Two bypass lines (116 and 118) may be required to connect the magnetic memory element (106) and one region (110) of the diode.

The magnetic memory element (106) typically includes three basic layers, a “free” ferromagnetic layer (120), an insulating tunnel junction layer (122), and a “pinned” ferromagnetic layer (124). In the free layer (120), the magnetization vectors are free to rotate under an external magnetic field. The magnetization vectors within the pinned layer (124) cannot rotate. The pinned layer (124) typically includes a ferromagnetic layer (126) and an anti-ferromagnetic layer (128), which pins the ferromagnetic layer (126). A tunneling current flows from one ferromagnetic layer (120), through the insulating layer (122), to the other ferromagnetic layer (124).

The two conductor lines (102 and 104) are used to read and write a selected MRAM (100). In a reading operation, a turn on transistor (not shown) allows a sense current to flow through the diode (107), the by-pass lines (116 and 118), and to the magnetic memory element (106). The sense current continues through the magnetic memory element (106) to the second conductor line (102). A voltage drop can then be used to determine the state of the magnetic memory element.

To write to a magnetic memory element (106), current is caused to flow through both conductor lines (102 and 104). The magnetic fields generated by the two conductor lines are superimposed causing the free ferromagnetic layer to align parallel to the fixed ferromagnetic layer.

An MRAM as presented below allows more precise control of conductor line thickness, thinner lines, and increased magnetic flux, thereby reducing energy consumption. In this disclosure, both of the conductor lines are deposited above the magnetic memory element. No CMP processing is required to be performed upon a conductor line. Each conductor line may be prepared by more precisely controllable sequences of deposition, lithographing and etching. Further, the structure presented below eliminates the by-pass lines to allow for a smaller memory cell footprint, and therefore denser memory cell packing.

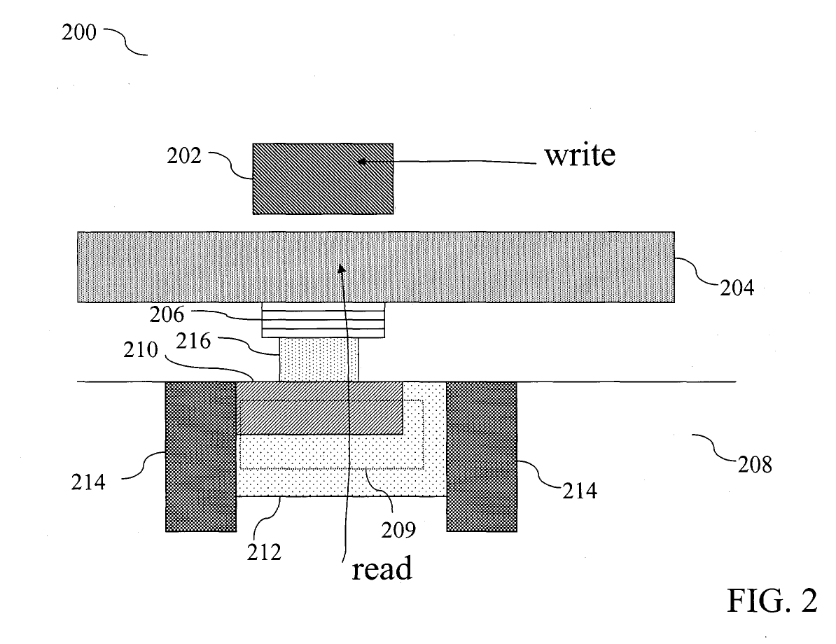

FIG. 2 illustrates a cross-section diagram of the principal components of a new MRAM (200). In this improved MRAM, both of the conductor lines (202 and 204) are located above the magnetic memory element (206).

A semiconductor element such as a transistor or diode is created in a substrate (208). The diode (209) with its n+ region (210) and p+ region (212) is located between the substrate (208) and the magnetic memory element (206) to prevent the stray current from affecting reading operations. Although a diode is shown as an example, a transistor might have been used instead of the diode, to act as a turn-on switch. Dielectric barriers (214) are created in the substrate (208) around the diode or transistor to isolate the cell (200) from other cells. Several sets of inter-metal layers and connecting vias (not shown for clarity) are typically located between the diode (209) and the magnetic memory element (206). The magnetic memory element (206) is fabricated on a connection line such as via (216) that is connected directly to the diode. In this configuration, as comparing to the MRAM in FIG. 1, no by-pass lines are required, as there is no need to “make a detour” to avoid contacting the conductor line (104 of FIG. 1) underneath the magnetic memory element (206).

As with the typical MRAM, the two conductor lines (202 and 204), crossing each other at right angles, are used to read and write a selected MRAM (200). The reading and writing process is not changed substantially from the typical MRAM. In a reading operation, a turn on transistor (not shown) allows a sense current to flow through the diode (209) directly through the via (216) to the magnetic memory element (206). The sense current continues through the magnetic memory element (206) to the second conductor line (204). The sense current produces a voltage drop over magnetic memory element (204) that can be used to determine the state of the magnetic memory element. This might be accomplished, for example, by using voltage comparators (not shown).

To write to a magnetic memory element (206), current is caused to flow through both conductor lines (202 and 204). The magnetic field generated by the first conductor line (202) is superimposed on the magnetic field generated by the second conductor line (204). The location of the second conductor (204) in this configuration does not substantially affect the combining of the magnetic fields. The combination realizes a large enough magnetic field to overcome the magnetic switch threshold causing the free ferromagnetic layer to align parallel to the fixed ferromagnetic layer. The other cells along the conductor lines are not disturbed.

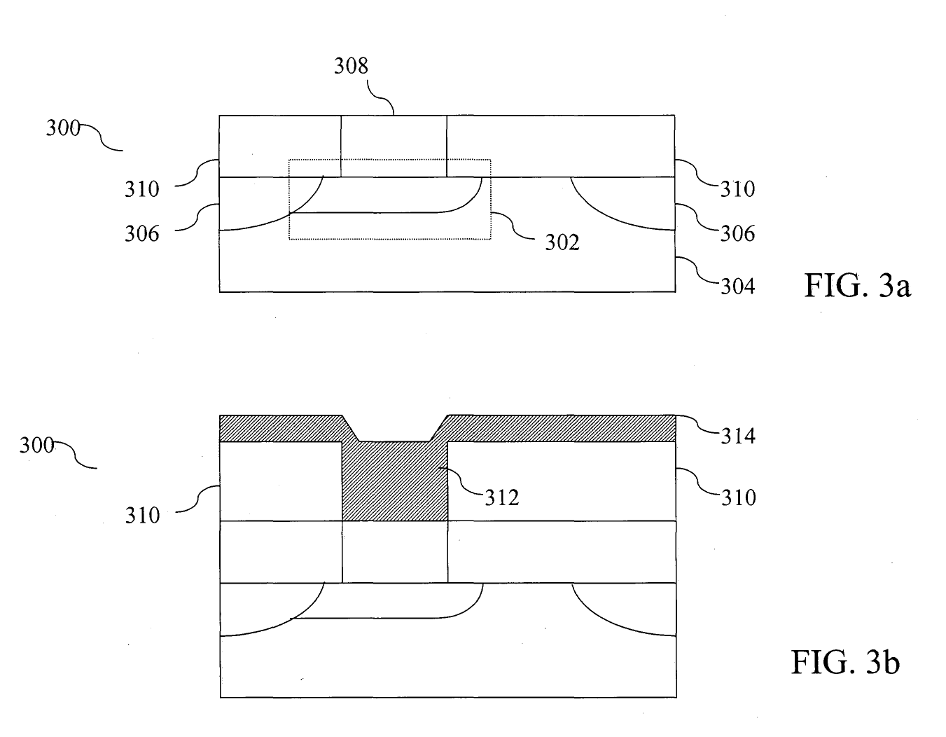

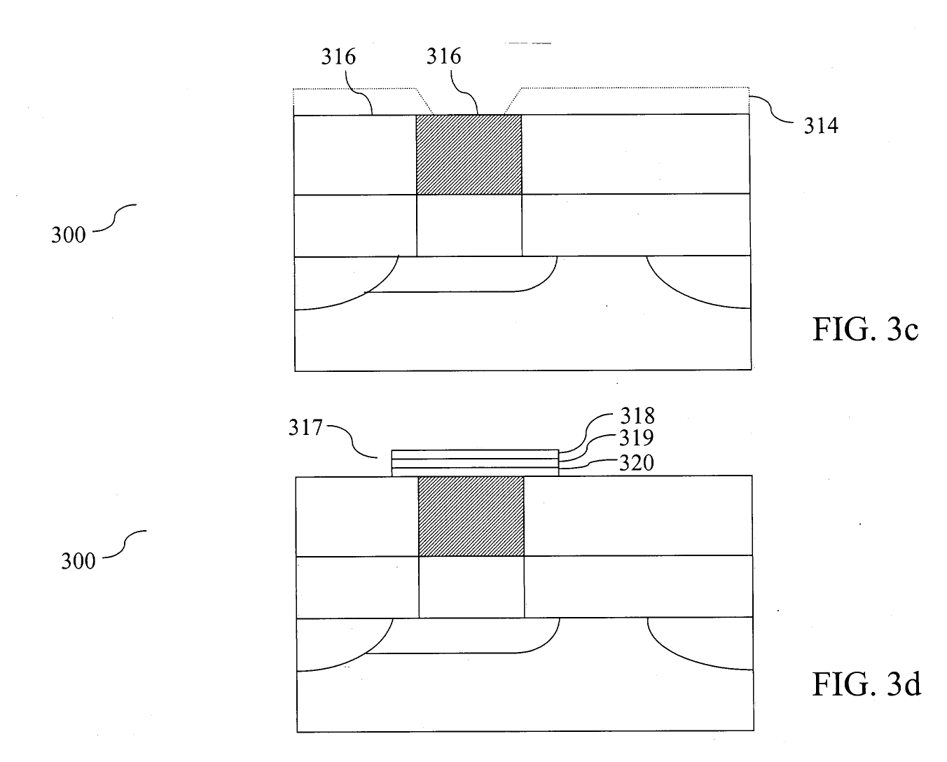

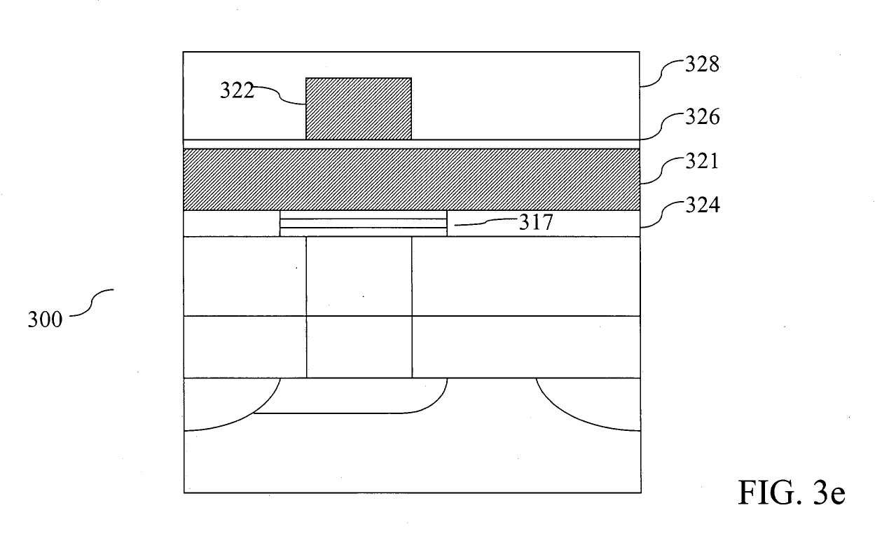

FIGS. 3a-3e illustrate the cross-section of the improved MRAM (300) in various stages of the fabrication process. FIG. 3a illustrates the fabrication of a semiconductor device (302) in the wafer substrate (304). Isolation regions (306) are created to isolate the MRAM (300). Several sets of inter-metal layer and connecting via are fabricated (not shown for clarity). A poly-silicon conductor (308) is created for connection with the magnetic memory element. The device is then covered with a dielectric layer (310).

FIG. 3b illustrates the etching of the dielectric layer (310) to create a metal connecting via (312) to the magnetic memory element. The etched hole is then filled with a predetermined metal (314). FIG. 3c illustrates the use of a CMP process to remove any excess metal (314) and to create a controlled flat surface (316) on which to fabricate the magnetic memory element.

FIG. 3d illustrates that a magnetic memory element (317) is then formed by deposition and patterning. The magnetic memory element (317) should have at least a free ferromagnetic layer (318), an insulating tunnel junction (319), and a pinned ferromagnetic layer (320).

In FIG. 3e, the first and second conductor lines (321 and 322) are subsequently formed on top of the magnetic memory element. The first conductor line (321) is deposited above the magnetic memory element (317) after a dielectric material (324) is formed for isolation purposes. As it is understood in the industry, the formation of the first conductor line may use a sequence of deposition, lithography and etching. The second conductor line is formed in a similar manner as the first conductor line. The thickness control over the entire wafer is much better by deposition than by a chemical-mechanical polish process. The thickness of the first or second conductor line may be between 200 Å to 4000 Å depending on the design of the MRAM. In a typical case, the thickness is below 1000 Å. It is noted that since the magnetic memory element (317) is well below both lines, non-CMP metal formation processes can be used because the locations in which the first or second conductor lines are formed are not in any way in the space that will be interfered by the physical existence of the magnetic memory element (317). The second conductor line and the first conductor line would be separated from each other by a dielectric spacer layer (326). With a dielectric layer (328) covering the MRAM cell (300), it is now deemed to be finished.

As both conductor lines are now processed above the magnetic memory element, and can be done using the standard processes unhindered by the physical existence of the magnetic memory element, the thickness of each conductor line can now be easily controlled. For example, by controlling variables in a metal deposition process, the lines can be made in any thickness using the easiest standard fabrication process known in the industry. The improved control of the thickness of these lines provides improved control of magnetic flux density, and thus reduces power consumption in the memory cell.

Further, because of the elimination of two bypass lines in the conventional MRAM layout that detours around one conductor line, there is no waste of space in the cell configuration and the footprint of each MRAM cell has been shrunk. As such, the cell density of such an MRAM device can be greatly increased. Therefore, it is clear that significant benefits are achieved over conventional approaches.

In addition, as semiconductor devices now have multiple layers of metal stacking up and separated by isolation layers, it is fully understood that the transistor or diode or any other semiconductor elements that is buried at any level can be connected to the magnetic memory element through a straight line connection. Such a straight line connection can comprise of one or more interconnects, vias or any other similar connection mechanism. It is noted that semiconductor processing technology is very mature today to make straight line connection, and unlike making “detours,” straight line connections can be made very economically.

The above disclosure provides many different embodiments, or examples, for implementing different features of the invention. Specific examples of components, and processes are described to help clarify the invention. These are, of course, merely examples and are not intended to limit the invention from that described in the claims.

While the invention has been particularly shown and described with reference to the preferred embodiment thereof, it will be understood by those skilled in the art that various changes in form and detail may be made therein without departing from the spirit and scope of the invention, as set forth in the following claims.

1. A magnetic memory device using two metal lines to control a combined magnetic field created thereof, comprising:
a horizontal structure device formed on a substrate;
a magnetic memory element connecting to the horizontal structure device at a first end thereof;
a first metal line connecting to a second end of the magnetic memory element; and
a second metal line crossing perpendicularly over the first metal line for jointly generating the combined magnetic field,
wherein the second metal line is on the side of the second end of the magnetic memory element.

2. The device of claim 1 further comprising an insulation layer separating the first metal line from the second metal line.

3. The device of claim 1 wherein the first metal line is fabricated using non-chemical-mechanical-polish processes.

4. The device of claim 1 wherein the thickness of the first or second metal line is between 200 Å to 4000 Å.

5. The device of claim 1 wherein the thickness of the first or second metal line is lower than 1000 Å.

6. The device of claim 1 wherein the magnetic memory element connects directly to the substrate on the first end through a straight line connection path.

7. The device of claim 6 wherein the straight line connection path passes through at least one metal layer from the first end of the magnetic memory element.

8. A magnetic memory device using two metal lines to control a combined magnetic field created thereof, comprising:
a horizontal structure transistor formed on a substrate having a substantially flat top surface;
a magnetic tunnel junction device (MTJ) connected to the horizontal structure transistor through a straight line connection line;
a first metal line over the MTJ and connected with the MTJ; and
a second metal line situated cross perpendicular to the first metal line, over the first metal line, and separated from the first metal line by an insulation region for jointly generating the combined magnetic field.

9. The device of claim 8 wherein the first metal line is fabricated without using a chemical-mechanical-polish process.

10. The device of claim 8 wherein the thickness of the first or second metal line is lower than 1000 Å.

11. The device of claim 8 wherein the MTJ further includes a free ferromagnetic layer, an insulating tunnel junction layer, and a pinned ferromagnetic layer.

12. A method for fabricating a memory device, comprising:
forming a transistor device on a substrate;
forming a magnetic tunnel junction device (MTJ) connected to the transistor device through a straight line connection line;
forming a first metal line over the MTJ and connected with the MTJ;
forming an insulation layer over the first metal line; and
forming a second metal line situated cross perpendicular to the first metal line and separated from the first metal line by the insulation region for jointly generating the combined magnetic field.

13. The method of claim 12 further comprising forming one or more interconnects along with the connection line to connect the transistor device and the MTJ through one or more metal layers.

14. The method of claim 12 wherein the forming a first metal line and the forming a second metal line use one or more non-chemical-mechanical-polish processes.

15. The method of claim 12 wherein the thickness of the first or second metal line is lower than 1000 Å.

16. The method of claim 12 wherein the thickness of the first or second metal line is between 200 Å to 4000 Å.
